(19) United States
(12) Patent Application Publication
(10) Pub. No.: US 2007/0269914 A1
(43) Pub. Date: Nov. 22, 2007

(54) Apparatus For Aligning Microchips On Substrate And Method For The Same

(75) Inventors: J. Andrew Yeh, Hsinchu County (TW); Gary C-W Tsai, Hsinchu County (TW); C. Max Hsieh, Hsinchu County (TW); Weng Wen-Jey, Hsinchu County (TW); Huang Yi-Ping, Hsinchu County (TW); Kao Chi-Chun, Hsinchu County (TW); Chou Ming-Hung, Hsinchu County (TW)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignees: National Tsing-Hua University, Hsinchu City (TW); Industrial Technology Research Institute, Hsinchu county (TW)

(21) Appl. No.: 11/552,955

(22) Filed: Oct. 25, 2006

(30) Foreign Application Priority Data
May 17, 2006 (TW) 095117552

(51) Int. Cl. H01L 21/00; H01L 21/68

(52) U.S. Cl. 438/26; 438/64; 414/755

(57) ABSTRACT

An apparatus for aligning microelements on a substrate and a method for the same are provided. The steps of the method include providing a substrate, forming a protruding structure on the substrate, providing a microelement, forming a microdroplet on the protruding structure, and forcing the microelement to contact the microdroplet. The surface tension of the microdroplet is used to move the microdroplet to a surface of the protruding structure.

### FIELD OF THE INVENTION

The present invention relates to an apparatus and a method for aligning microelements (e.g., dies and microchips) on a substrate, and more particularly to an apparatus and a method for aligning microelements on a substrate using a protruding structure.

### BACKGROUND OF THE INVENTION

In recent years, many electronic devices exist depend on microchips for their functionalities. Two typical products are Radio Frequency Identification Tags (RFID Tag) and Light Emitter diodes (LED). The microchips have properties of very tiny sizes, low fabrication prices but high demands. In the total component costs of a passive RFID Tag, the cost of assembly takes a major part (over 20 percentages). Therefore, how to decrease the cost but increase the capacity of assembly is an important problem to be solved. Please refer to FIG. 1, which shows one kind of RFID tag 10 produced by RVB System group. A microchip 11 is placed inside the RFID tag 10, and a square antenna 12 extends from inside to outside thereof. Please refer to FIG. 2, which shows a near-IR LED 20 produced by Roithner Light Technik. The LED includes a die 21, a wire bond and wire 22, a silicon substrate 23, a printed circuit board 24, and a reflector 25.

The traditional IC die assembly is performed by a technique named picking-and-placing. Westinghouse electric corp. had owned patients related to the technique from 1983. Picking-and-placing means taking a die from a sawed wafer, and transporting it to a specific position on the substrate with a mechanical arm. If a solder bump having surface tension thereon is used as a signal joint in a traditional IC assembly process, the self-alignment function will be achieved when the solder bump reflows. But the solder bump has a size far smaller than that of the IC die and is located on the edge of the die, so a mechanical arm is still required to align the die more precisely. Because the requisition of the precision for the mechanical arm is so strict that at most five microelements can be aligned at a time, the aligning model is still limited to a one-dimensional model. For the same reason, the design of the mechanical arm is very complex and usually needs a feedback control system. Please refer to FIG. 3, which shows a picking-and-placing device 30 produced by GDSI Company.

Please refer to FIG. 4, which shows another microelements assembly technique named Fluidic Self Assembly (FSA) and brought up by Prof. Smith. In an FSA process, a special procedure is used to etch a structure on the back of the LED, and an array comprising a plurality of concaves 42 having corresponding shapes is etched on a silicon substrate 41. Then the silicon substrate 41 and a large number of LED dies 40 are placed into a fluid such as water, and the LED dies 40 are combined with the concaves 42 on the substrate 41 fast because of fluid movement and corresponding shapes. The following patents such as U.S. Pat. Nos. 4,398,863, 5,961,168, 5,783,856, 5,824,186, 5,904,545, 6,527,964, 6,623,579, and 6,864,570 all focus on changing the design of LED dies to increase the precision of aligning, and simplify the following assembly process. For example, using a hydrophobic material on the surfaces of the substrate 41 and the LED dies 40 increase precision and yield. Alien also uses the same process in the RFID tag assembly.

From the above description, the prior art of aligning microelements on a substrate includes picking-and-placing and FSA, and the respective drawbacks thereof are as follows:

I. Picking-and-Placing

1. Aligning microelements with a mechanical arm needs a complex system, comprising a position sensor system, a signal processing system, and a position adjustment system. Because of the complexity and the mechanical system, at most only five microelements can be aligned at a time, so it is very difficult to decrease the aligning time.

2. When the size of the microelement becomes smaller, the control system of the mechanical arm becomes more complex, which increases the unit cost.

3. The vacuum attraction holding apparatus used in the mechanical arm is difficult to attract the microelement having a size smaller than millimeter.

II. Fluidic Self Assembly (FSA)

1. In an FSA process, it is needed to etch a special shape on the back of the microelement, and change the surface thereon from the hydrophilic one to the hydrophobic one.

2. In an FSA process, a large number of microelements are placed into an FSA fluid, and a vibrator is then used to accelerate the combination rate of microelements with concaves on the substrate. The whole system, which comprises a microelement recycling system, an FSA fluid control system, and a drying system, is very huge and complex.

3. In an FSA process, a large number of microelements are placed into an FSA fluid for a long time and the unused ones are recycled, which raises the risk of damaging the microelements.

4. In an FSA process, a huge amount of microelements that is far more than what is really needed in assembly is required to increase the combination rate, but the incorrect alignment is hard to avoid. Therefore, such an alignment apparatus is really not ideal.

From the above description, it is known that how to develop an apparatus and method for aligning microelements on the substrate, which have a better efficiency than the mechanical system without the need for a recycle system, has become a major problem waited to be solved. In order to overcome the drawbacks in the prior art, an improved apparatus and method for aligning microelements on the substrate are provided. The particular designs in the present invention not only solve the problems described above, but also are easy to be implemented. Thus, the invention has the utility for the industry.

### SUMMARY OF THE INVENTION

In accordance with an aspect of the present invention, a method for aligning a microelement on a substrate is provided. The method comprises steps of forming a protruding structure on the substrate, forming a microdroplet on the protruding structure, providing a microelement, and forcing the microelement to contact the microdroplet, wherein the microdroplet has surface tension and the surface tension moves the microelement to the surface of the protruding structure and thereby the microelement is aligned on the substrate.

Preferably, forming the protruding structure comprises forming a encircling groove on the substrate by a method selected from a group consisting of an etching, a pressurized pressing and a gravity pressing, and thereby the protruding structure higher than the encircling groove is formed on the substrate.

Preferably, forming a protruding structure is performed by a method selected from a group consisting of screen-printing, tape adhesion and a film forming.

Preferably, forming a microdroplet is performed by a method selected from a group consisting of injecting the microdroplet by a spray head, dripping the microdroplet by a dispenser and forming the microdroplet by a pipe installed in the protruding structure.

Preferably, providing a microelement is performed by a method selected from a group consisting of throwing the microelement from a vibrator, flipping the microelement from a mechanical apparatus, pushing the microelement out from a mechanical apparatus having at least one needle, dropping the microelement from a fast-shifting tray, dropping the microelement from a vacuum attraction holding apparatus, and blowing the microelement from a gas blowing apparatus.

In accordance with another aspect of the present invention, an apparatus for aligning a microelement is provided. The apparatus includes a microdroplet producer, and a substrate comprising a protruding structure mounted thereon, wherein a microdroplet of the microdroplet producer formed on a surface of the protruding structure is used for aligning the microelement on the surface of the protruding structure.

Preferably, the protruding structure further comprises a margin being lower than the surface of the protruding structure.

Preferably, the protruding structure has a size being equal to that of the microelement.

Preferably, the protruding structure has a shape identical to that of the microelement, and thereby the microelement is self-aligned on the substrate.

Preferably, the apparatus further comprises edge effect and a ratio of a cross-section area of the microdroplet to the protruding structure, wherein the ratio of the cross-section area is ranged from a half to a quarter. The microdroplet has a position with the smallest surface free energy, and the surface tension is an adhesive force, whereby the edge effect is obtained and the microelement is adjusted with the position accordingly.

Preferably, the microelement has a first surface. The protruding structure is made of a waterproof material, and has a second surface the same as that of the first surface being one of a hydrophilic surface and a hydrophobic surface.

Preferably, the apparatus further comprises a plurality of protruding structures to be arranged a matrix.

Preferably, the microdroplet is made of a material being selected from a group consisting of water, oil, alcohol, liquid gum, mercury, and liquid tin.

Preferably, the substrate is one of a soft assembly substrate and a hard assembly substrate.

Preferably, the substrate is a recyclable substrate for serving as a vehicle to transport the microelement in an assembly process.

In accordance with a further aspect of the present invention, an apparatus for aligning a microelement is provided. The apparatus comprises a substrate and a producer generating a substance having surface tension. The substrate comprises an aligning area having a surface and a margin surrounding and being lower than the aligning area, wherein the substance having surface tension is generated between the microelement and the aligning area, whereby the surface tension moves the microelement to the surface.

Preferably, the producer is a droplet producer, and the substance having surface tension is a microdroplet.

In accordance with further another aspect of the present invention, an apparatus for aligning a microelement is provided. The apparatus comprises a substrate comprising an aligning area that has a surface, and a margin surrounding and being higher than the aligning area mounted thereon. The apparatus also comprise means for providing a substance having surface tension to the aligning area, whereby the microelement is aligned on the surface.

Preferably, the aligning area is a concave structure.

In accordance with further another aspect of the present invention, a method for aligning a microelement is provided. The method comprises steps of forming an aligning area having a surface and a margin surrounding the area on the substrate, wherein the aligning area is higher than the margin, forming a microdroplet having surface tension on the aligning area, and forcing the microelement to contact the microdropet, wherein the surface tension moves the microelement to the surface.

Preferably, the aligning area is a protruding structure.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a top view of the RFID Tag in the prior art;

FIG. 2 is a top view of the LED in the prior art;

FIG. 3 is a three-dimensional diagram of a picking-and-placing device in the prior art;

FIG. 4 is a schematic diagram of the procedure for aligning dies in an FSA process in the prior art;

FIGS. 5(A)-5(B) are top and side views showing the protruding structure according to a preferred embodiment of the present invention;

FIGS. 5(C)-5(D) are top and side views showing the formation of a microdroplet according to a preferred embodiment of the present invention;

FIGS. 5(E)-5(F) are top and side views showing the microdroplet being contacted with a microelement according to a preferred embodiment of the present invention;

FIG. 5(G) is a schematic view showing the self-alignment of the microelement according to a preferred embodiment of the present invention;

FIG. 6(A) is a top view showing another method for forming a protruding structure on a substrate according to a preferred embodiment of the present invention;

FIG. 6(B) is a cross-sectional view showing another method for forming a protruding structure on a substrate along B′-B line according to a preferred embodiment of the present invention;

FIG. 6(C) is a cross-sectional view showing another method for forming a protruding structure on a substrate along A′-A line according to a preferred embodiment of the present invention;

FIG. 7(A) is a top view showing a further method for forming a protruding structure on a substrate according to a preferred embodiment of the present invention;

FIG. 7(B) is a cross-sectional view showing a further method for forming a protruding structure on a substrate along B′-B line according to a preferred embodiment of the present invention;

FIG. 7(C) is a cross-sectional view showing another method for forming a protruding structure on a substrate along A′-A line according to a preferred embodiment of the present invention;

FIGS. 8(A)-8(B) are schematic diagrams showing a method for forming the microdroplet of FIG. 5;

FIG. 9 is a schematic diagram showing another method for forming the microdroplet of FIG. 5;

FIG. 10 is a three-dimensional diagram of a vibrator throwing the microelement of FIG. 5;

FIGS. 11(A)-11(C) are side views showing the displacement when the ratio of a cross-section area of the microdroplet to the protruding structure is smaller than half, ranged from half to one, and equal to one, respectively;

FIG. 12 is a schematic diagram showing the relative curve between the surface free energy and the displacement of a microdroplet; and

FIG. 13 is a cross-sectional view showing the formation of a concave structure that is corresponding to the protruding structure of FIG. 5.

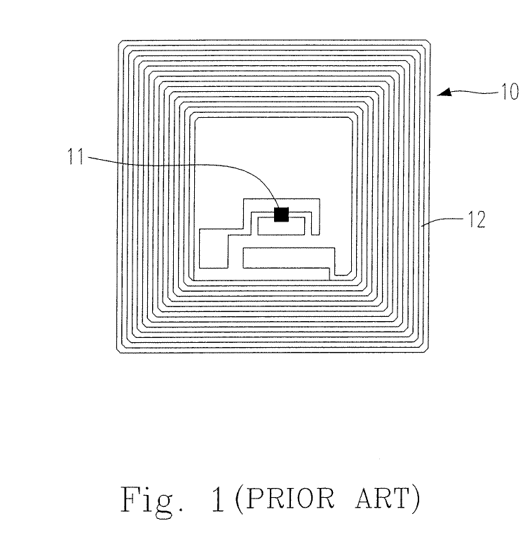

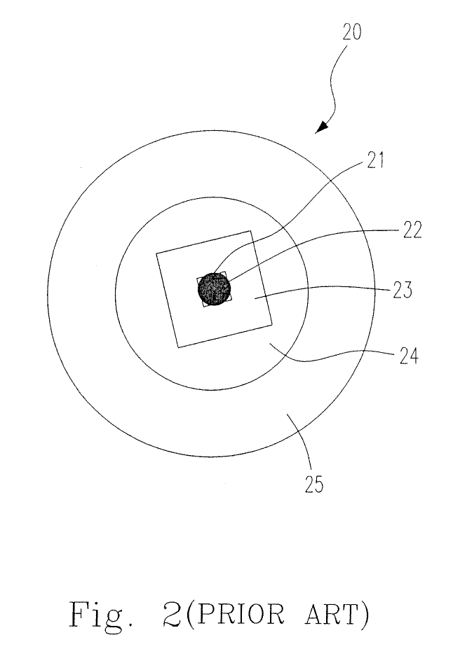

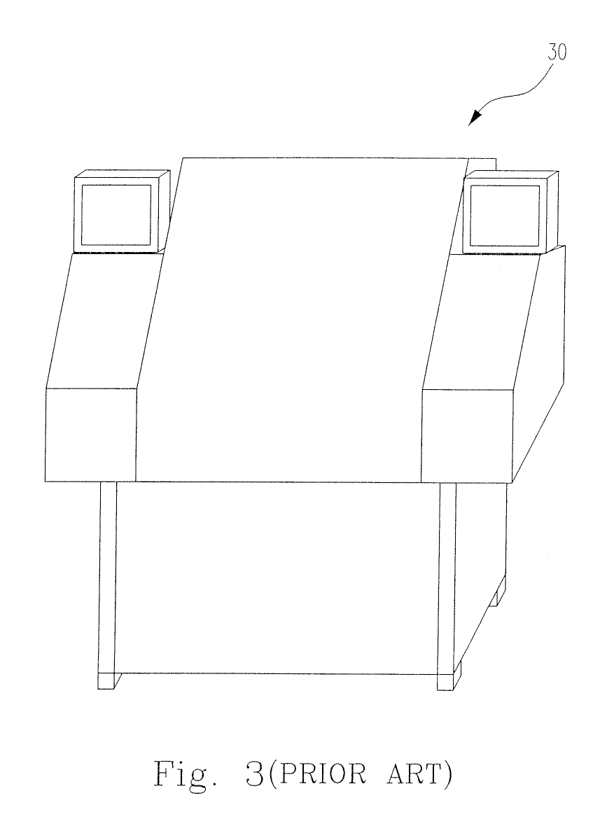

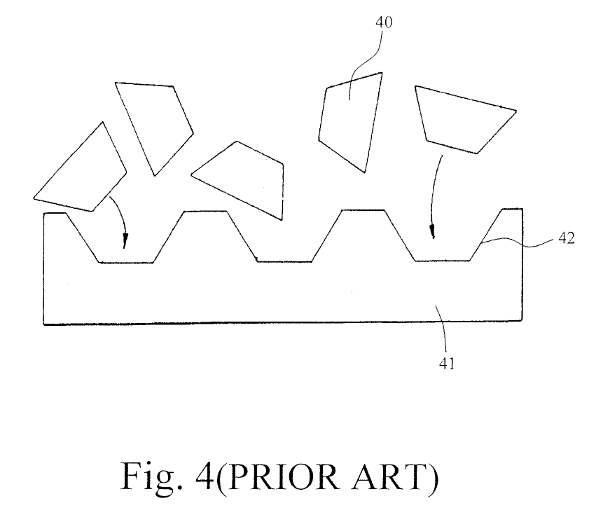

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

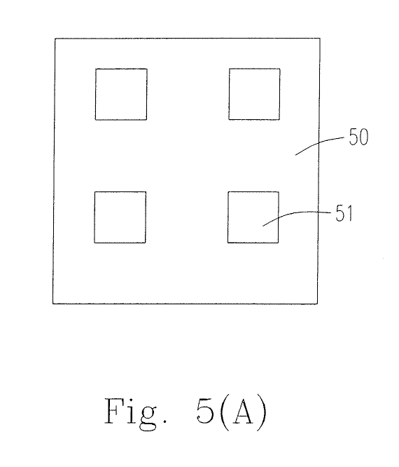

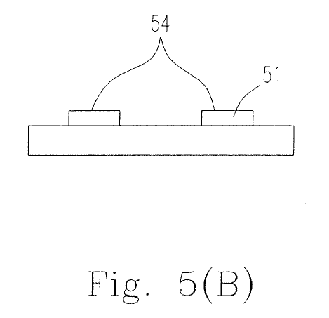

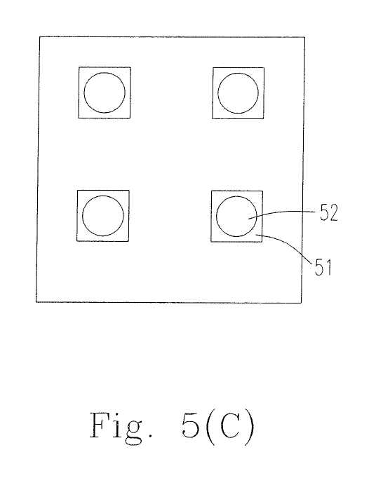

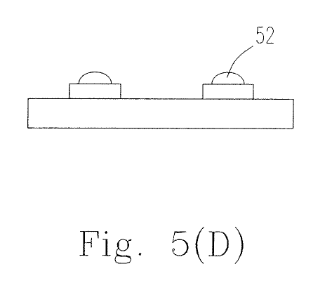

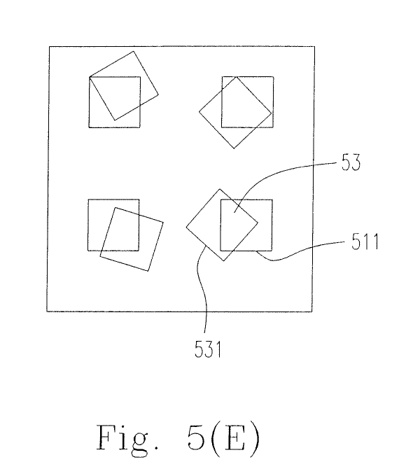

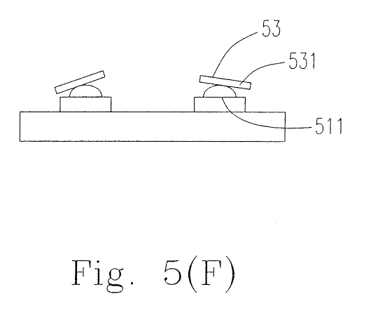

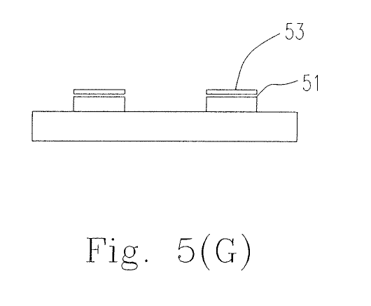

Please refer to FIGS. 5(A)-5(G), which show a new method of aligning the microelement on the substrate. The method comprises steps of forming a protruding structure 51 on the substrate 50, forming a microdroplet 52 on the protruding structure 51, providing a microelement 53, and forcing the microelement 53 to contact the microdroplet 52, wherein the microdroplet 52 has surface tension and the surface tension moves the microelement 53 to the surface 54 of the protruding structure 51 as illustrated in FIG. 5(B), and thereby the microelement is aligned on the substrate.

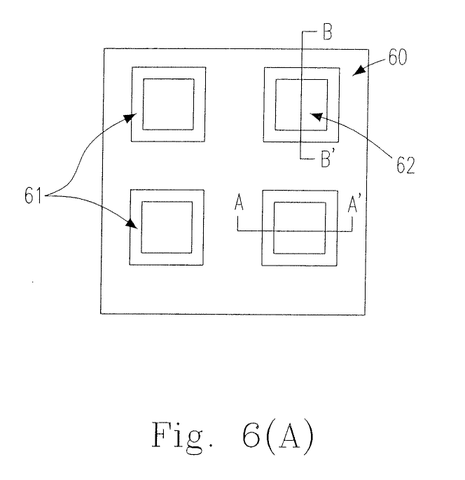

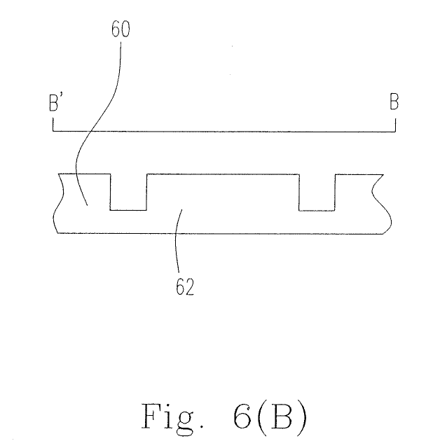

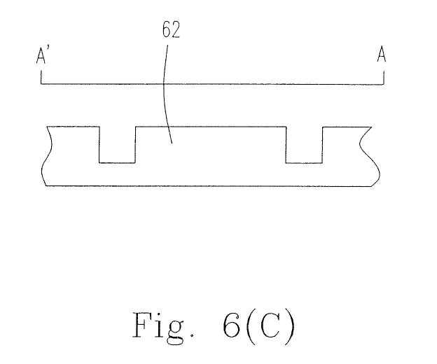

Please refer to FIGS. 6(A)-6(C). FIG. 6(A) is a top view showing another method for forming a protruding structure on a substrate according to a preferred embodiment of the present invention. FIG. 6(B) is a cross-sectional view showing another method for forming a protruding structure on a substrate along B′-B line according to a preferred embodiment of the present invention. FIG. 6(C) is a cross-sectional view showing another method for forming a protruding structure on a substrate along A′-A line according to a preferred embodiment of the present invention. The method of FIGS. 6(A)-6(C) comprises forming a encircling groove 61 on the substrate 60 by a method selected from a group consisting of an etching, a pressurized pressing and a gravity pressing. The protruding structure 62 higher than the encircling groove 61 is formed. The detailed steps of the method include making a photomask having a pattern thereon, transcribing the pattern into the photoresist on the substrate 60, etching the pattern on the substrate 60, and removing the photoresist, thereby forming the protruding structure 62 on the substrate 60.

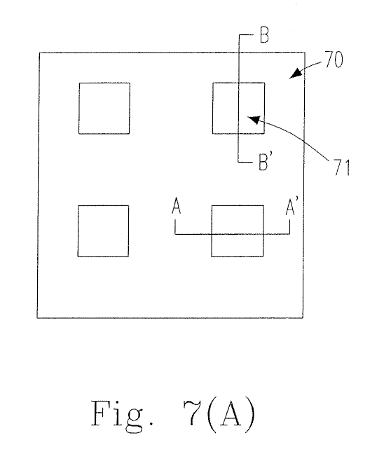

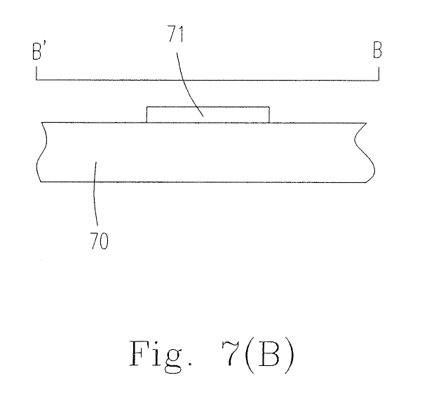

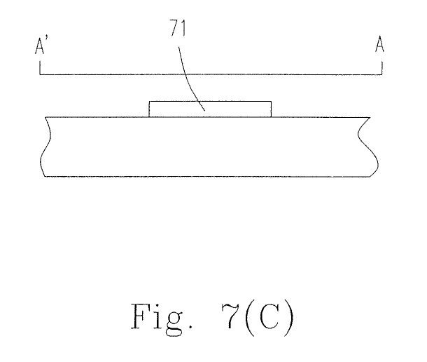

Please refer to FIGS. 7(A)-7(C). FIG. 7(A) is a top view showing a further method for forming a protruding structure on a substrate according to a preferred embodiment of the present invention. FIG. 7(B) is a cross-sectional view showing a further method for forming a protruding structure on a substrate along B′-B line according to a preferred embodiment of the present invention. FIG. 7(C) is a cross-sectional view showing another method for forming a protruding structure on a substrate along A′-A line according to a preferred embodiment of the present invention. In the method of FIGS. 7(A)-7(C), a protruding structure 71 is formed on a substrate 70, which is performed by a method selected from a group consisting of screen-printing, tape adhesion and a film forming. Therefore, the material of the protruding structure 62 is the same as that of the substrate 60, but the material of the structure 71 and that of the substrate 70 are different.

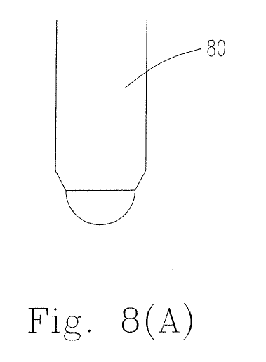

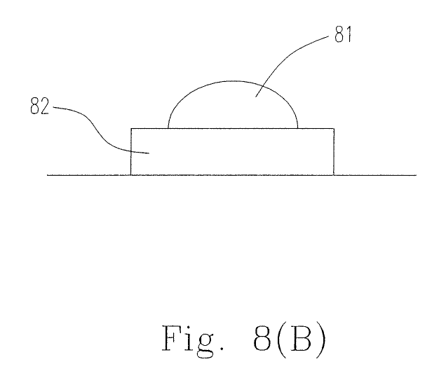

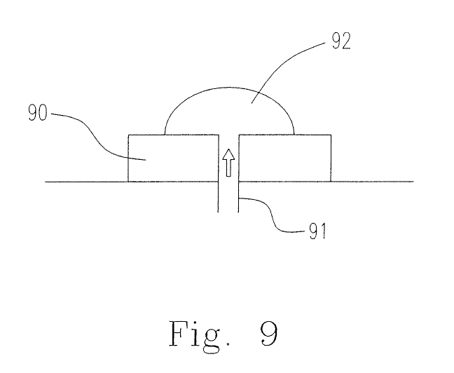

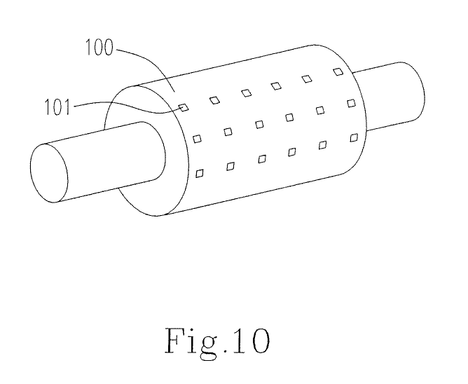

Please refer to FIGS. 8(A)-8(B). FIGS. 8(A)-8(B) are schematic diagrams showing a method for forming a microdroplet of FIG. 5. As shown in FIGS. 8(A)-8(B), forming a microdroplet 81 on a protruding structure 82 is performed by one of injecting and dripping the microdroplet 81 by a microdroplet producer 80. Please refer to FIG. 9, which is a schematic diagram showing another method for forming the microdroplet of FIG. 5. As shown in FIG. 9, forming a microdroplet 92 is performed by the fluid flowing from a pipe 91 installed in the protruding structure 90. Please refer to FIG. 10, which is a three-dimensional diagram of a vibrator throwing the microelement of FIG. 5. As illustrated in FIG. 10, providing a microelement 101 is performed by throwing the microelement 101 with a vibrator 100. The other methods include flipping the microelement from a mechanical apparatus, pushing the microelement out from a mechanical apparatus having at least one needle, dropping the microelement from a fast-shifting tray, dropping the microelement from a vacuum attraction holding apparatus, and blowing the microelement from a gas blowing apparatus.

In accordance with one aspect of the present invention, an apparatus for aligning a microelement is provided. The apparatus includes the microdroplet producer 80 (e.g., a spray head, a dispenser or a row of spray heads, which can control the size of the microdroplet 52 and spurt a plurality of microdroplets 52), and the substrate 50 comprising a protruding structure 51 mounted thereon, wherein the microdroplet 52 of the microdroplet producer 80 is formed on a surface of the protruding structure 51. The margin 61 that is lower than the structure 51 enables the microelement 53 to contact the microdroplet 52, and the surface tension of the microdroplet 52 is used to move the microelement 53 to the surface 54 of the protruding structure 51.

Further yet, the microelement 53 is self-aligned on the substrate 50 by the microdroplet 52. The microelement 53 can be replaced with any other micro objects for special purposes. Because of edge effect, the microelement 53 is adjusted to the only position with the smallest free energy. For the same effect, the microdroplet 52 is kept just on the protruding structure 51 and won't contact the substrate 50 to disturb the self-alignment.

No matter where the microelement 53 contacts the microdroplet 52 in the beginning, the microelement 53 finally moves to the surface 54 according to the shape of the structure 50, and thereby the microelement 53 is self-aligned on the substrate 51. Because the volume of the microelement 53 is so tiny that the gravity effect is neglected. For the self-alignment function, the position control system of the mechanical arm is simpler compared with the prior art, and the complexity of an assembly process is also reduced.

The present invention can be applied in the way of array manufacture, increasing the capacity per unit time, and reducing the assembly cost. The present invention also can be performed using the existing microelements 53 without considering the shape and surface character thereof. When the microelement 53 contacts with the microdroplet 52, the self-alignment will be finished within one second and the microelement 53 will be adjusted to the position with the smallest surface free energy. Because of the edge effect of the protruding structure 51, the boundaries of the microelement 53 are fixed, and hence there is only position with the smallest surface free energy on the horizontal surface.

The protruding structure 51 has a shape and volume equal to that of the microelement 53. According to the experiment results, the self-alignment function in an even-edges shape is better than that in an odd-edges shape. When the ratio of a cross-section area of the microdroplet 52 to the protruding structure 51 is ranged from a half to a quarter, the adhesive effect is best, and the surface tension is an adhesive force, whereby the edge effect is obtained, which means the distance between a immovable side 511 and a movable side 531 is shortened, and the microelement is adjusted to the position with the smallest surface free energy accordingly.

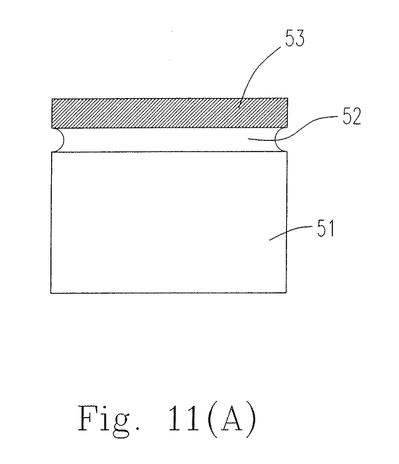

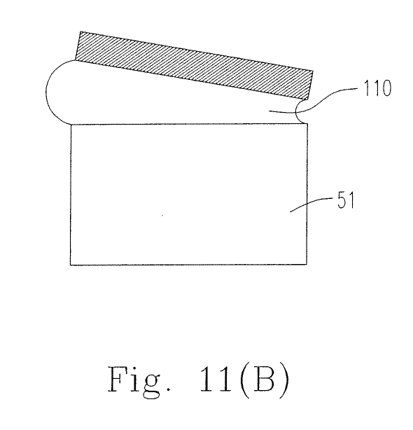

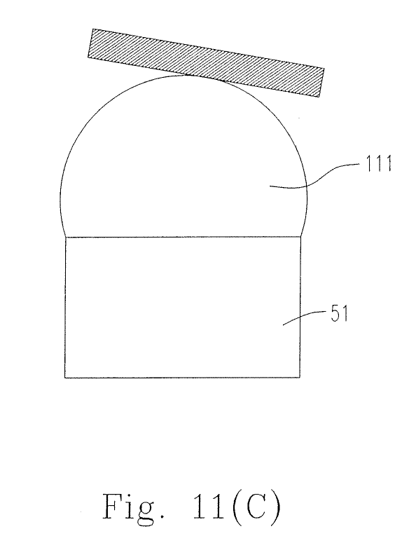

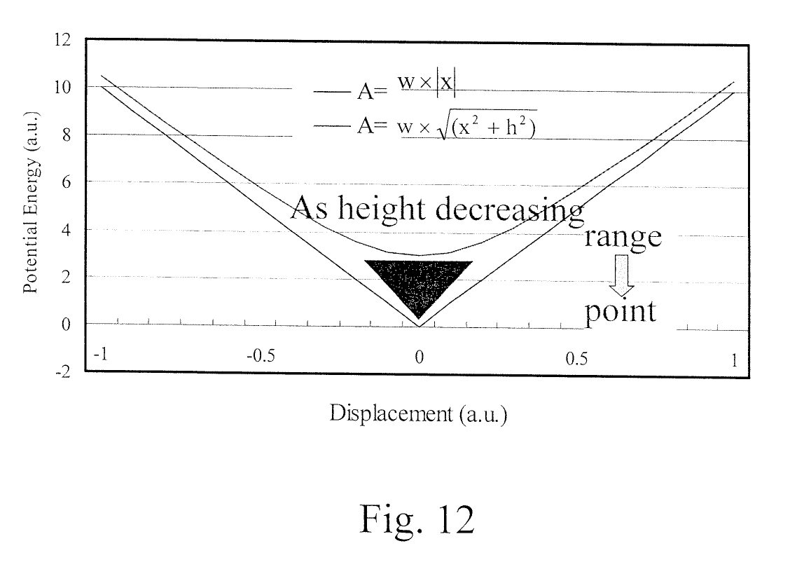

Please refer to FIG. 11(A), which shows the motion when the ratio of a cross-section area of the microdroplet 52 to the protruding structure 51 is smaller than a half. FIGS. 11(B)-11(C) show the motion when the ratio of a cross-section area of the microdroplet 52 to the protruding structure 51 is ranged from half to one, and equal to one, respectively. As shown in FIGS. 11(B)-11(C), the adhesive effect is worse than that in FIG. 11(A). Furthermore, FIG. 11(C) shows the motion when the cross-section area of the microdroplet 52 is equal to that of the protruding structure 51. The relative curve showing the displacement of the microdroplet 52 to the surface free energy is shown in FIG. 12, which shows the smallest free energy is obtained when the displacement between the immovable side 511 and the movable side 531 is zero.

The microelement 53 has a first surface, and the protruding structure 51 is made of a waterproof material, having a second surface the same as that of the first surface being one of a hydrophilic surface and a hydrophobic surface. This means the hydrophilic or hydrophobic surface is not the point, the point is the formation of the surface tension. The protruding structures 51 and other protruding structures can be arranged a matrix as shown in FIG. 5(A). The microdroplet can be made of a material being selected from a group consisting of water, oil, alcohol, liquid gum, mercury, liquid tin (liquid metals), and other liquid solvent. The substrate 50 is one of a soft assembly substrate and a hard assembly substrate, which means the present invention can be applied in the flip-chip assembly, soft-substrate assembly, etc., to improve the efficiency and reduce the cost. The substrate 50 can be replaced with a recyclable substrate for serving as a vehicle to transport the microelement in an assembly process.

As for the permeable range of the microdroplet 52 contact angle measured at the surface edge of the protruding structure 51, it follows the Gibbs' inequality as:

θ₀≦θₐₚₚ≦(180°−φ)+θ₀

wherein θ₀ is the intrinsic contact angle, θₐₚₚ is the contact angle of the droplet measured at the solid surface edge, and φ is the angle measured between the two connecting solid surfaces. The relative equation of the microdroplet 52 surface energy is as follows:

E=∫γdA

wherein A is the interface area, and γ is the surface tension. The contact angles between different kinds of materials and water droplets are shown in the following table:

| | water droplet contact angle |
|---|---|
| Glass | 41° |
| ITO | 61° |
| Parylene C | 76° |
| PDMS | 103° |
| SU8 | 73° |
| Teflon | 105° |

In accordance with another aspect of the present invention, an apparatus for aligning a microelement is provided. The apparatus includes a producer (e.g., a microdroplet producer 80) generating a substance having surface tension. The apparatus also includes the substrate 50, comprising a working area. The working area includes an aligning area 51 having a surface 54 and a margin 61 surrounding and being lower than the aligning area, wherein the substance having surface tension (e.g., the microdroplet 52) is formed on the aligning area and between the microelement 53 and the substrate 50, whereby the surface tension moves the microelement 53 to the surface 54, and the substance having surface tension is the microdroplet 52.

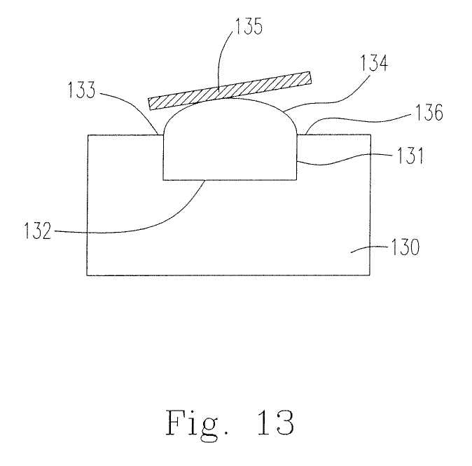

In accordance with another aspect of the present invention, an apparatus for aligning a microelement as shown in FIG. 13 is provided. The apparatus includes a producer (e.g., the microdroplet producer 80) for providing a substance having surface tension and a substrate 130. The substrate 130 includes an aligning area 132, which is corresponding to the protruding structure 51 as shown in FIG. 5, and a margin 133 having a surface 136 thereon. The margin 133 surrounds and is higher than the aligning area 132, which has a smaller size than that of the microelement 135 and is a concave structure.

In accordance with another aspect of the present invention, a method for aligning a microelement on a substrate is provided. The first step of the method is forming an aligning area on the surface 54 of the protruding structure 51 on the substrate 50 and a margin 61 surrounding the aligning area on the substrate, wherein the aligning area is higher than the margin 61. The second step is forming the microdroplet 52 having surface tension on the aligning area and forcing the microelement 53 to contact the microdropet 52, wherein the surface tension moves the microelement 53 to the surface 54. The aligning area in the method is the surface 54 of the protruding structure 51.

In conclusion, due to the formation of a microdroplet having surface tension on the protruding structure, the surface tension moves the microelement to the surface of the protruding structure. By etching, a circling groove and the protruding structure being higher than the circling groove are formed on the substrate. Accordingly, the present invention can effectively solve the problems and drawbacks in the prior art, and thus it fits the demand of the industry and is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for aligning a microelement on a substrate, comprising steps of:
(a) forming a protruding structure on the substrate;
(b) forming a microdroplet on the protruding structure, wherein the microdroplet has surface tension;
(c) providing a microelement; and
(d) forcing the microelement to contact the microdroplet, wherein the surface tension moves the microelement to the protruding structure and thereby the microelement is aligned on the substrate.

2. The method as claimed in claim 1, wherein the step (a) includes forming an encircling groove on the substrate by a method selected from a group consisting of an etching, a pressurized pressing and a gravity pressing, and thereby the protruding structure higher than the encircling groove is formed on the substrate.

3. The method as claimed in claim 1, wherein the step (a) is performed by a method selected from a group consisting of screen-printing, tape adhesion and a film forming.

4. The method as claimed in claim 1, wherein the step (b) is performed by a method selected from a group consisting of injecting the microdroplet by a spray head, dripping the microdroplet by a dispenser and forming the microdroplet by a pipe installed in the protruding structure.

5. The method as claimed in claim 1, wherein the step (c) is performed by a method selected from a group consisting of throwing the microelement from a vibrator, flipping the microelement from a mechanical apparatus, pushing the microelement out from a mechanical apparatus having at least one needle, dropping the microelement from a fast-shifting tray, dropping the microelement from a vacuum attraction holding apparatus, and blowing the microelement from a gas blowing apparatus.

6. An apparatus for aligning a microelement, comprising:
a microdroplet producer; and
a substrate comprising a protruding structure mounted thereon, wherein a microdroplet of the microdroplet producer formed on a surface of the protruding structure is used for aligning the microelement on the surface of the protruding structure.

7. The apparatus as claimed in claim 6, wherein the protruding structure further comprises a margin being lower than the surface of the protruding structure.

8. The apparatus as claimed in claim 6, wherein the protruding structure has a size being equal to that of the microelement.

9. The apparatus as claimed in claim 6, wherein the protruding structure has a shape identical to that of the microelement, and thereby the microelement is self-aligned on the substrate.

10. The apparatus as claimed in claim 6, further comprising edge effect and a ratio of a cross-section area of the microdroplet to the protruding structure, wherein the ratio of the cross-section area is ranged from a half to a quarter, the microdroplet has a position with the smallest surface free energy, and the surface tension is an adhesive force, whereby the edge effect is obtained and the microelement is adjusted with the position accordingly.

11. The apparatus as claimed in claim 6, wherein the microelement has a first surface, the protruding structure is made of a waterproof material, and has a second surface the same as that of the first surface being one of a hydrophilic surface and a hydrophobic surface.

12. The apparatus as claimed in claim 6, further comprising a plurality of the protruding structures to be arranged a matrix.

13. The apparatus as claimed in claim 6, wherein the microdroplet is made of a material being selected from a group consisting of water, oil, alcohol, liquid gum, mercury, and liquid tin.

14. The apparatus as claimed in claim 6, wherein the substrate is one of a soft assembly substrate and a hard assembly substrate.

15. The apparatus as claimed in claim 6, wherein the substrate is a reusable substrate for serving as a vehicle to transport the microelement in an assembly process.

16. An apparatus for aligning a microelement, comprising:
a producer generating a substance having surface tension; and
a substrate, comprising:
an aligning area having a surface; and
a margin surrounding and being lower than the aligning area, wherein the substance having surface tension is generated between the microelement and the aligning area, whereby the surface tension moves the microelement to the surface.

17. The apparatus as claimed in claim 16, wherein the producer is a droplet producer, and the substance having surface tension is a microdroplet.

18. An apparatus for aligning a microelement, comprising:
a substrate, comprising:
an aligning area having a surface; and
a margin surrounding and being higher than the aligning area mounted thereon; and
means for providing a substance having surface tension to the aligning area, whereby the microelement is aligned on the surface.

19. The method as claimed in claim 18, wherein the aligning area is a concave structure.

20. A method for aligning a microelement on the substrate, comprising steps of:
forming an aligning area having a surface and a margin surrounding the aligning area on the substrate, wherein the aligning area is higher than the margin;
forming a microdroplet having surface tension on the aligning area; and
forcing the microelement to contact the microdropet, wherein the surface tension moves the microelement to the surface.

21. The method as claimed in claim 20, wherein the aligning area is a protruding structure.
